(19) United States
(12) Patent Application Publication
(10) Pub. No.: US 2010/0132804 A1
(43) Pub. Date: Jun. 3, 2010

(54) Pressure Equalizing Housing Device

(76) Inventor: Yefim Kereth, Rehovot (IL)

Correspondence Address: STETINA BRUNDA GARRED & BRUCKER, 75 ENTERPRISE, SUITE 250, ALISO VIEJO, CA, 92656, US

(21) Appl. No.: 11/990,129

(22) PCT Filed: Aug. 8, 2006
(86) PCT No.: PCT/IL2006/000913

§ 371 Date: Feb. 7, 2008

Related U.S. Application Data
(60) Provisional application No. 60/707,164, filed on Aug. 11, 2005.

(30) Foreign Application Priority Data
Jul. 20, 2006 (IL) 176983

(51) Int. Cl. F16T 1/00

(52) U.S. Cl. 137/171

(57) ABSTRACT

There is provided a pressure-equalizing housing device, including a rigid housing having a coupling end and configured to contain at least one instrument. The coupling end of the housing is adapted to be sealable to a radiation transmittable surface. An opening made in a wall of the housing enables fluid to pass therethrough, and the housing and surface delimit an interior space communicating with the exterior of the housing via the opening. There is also provided a pressure-influenced member forming an expandable and retractable volume body, a portion of which member is located adjacent to, or the interior of which member communicates with, the opening, for equalizing the pressure inside and outside the housing.

### FIELD OF THE INVENTION

The present invention relates to a pressure equalizing housing device for preventing the entrance of moisture or other contaminators into the interior of the housing device.

### BACKGROUND OF THE INVENTION

Electro-optical, electronic and other instruments may be heavily affected, and their components may be irreversibly damaged, by excessive moisture. As used herein, the term “moisture” is intended to refer to water which is diffused, penetrated or condensed from the ambient atmosphere, whether in liquid or vapor form. Housings, enclosing cameras, optics, electronics and instruments, undergo thermal cycling by external or internal heat source(s) and due to on/off cycling within the enclosure, result in moisture built-up therein. A relatively simple way of dispensing moisture is to provide greater ambient airflow across, or through, the enclosure. Ambient air, however, may be contaminated by dust and other contaminants, unwanted within the housing enclosure, and moreover, when components are located in an enclosed housing, it can be very difficult to provide adequate airflow to reduce moisture. Whenever the housing is non-hermetically sealed, it is possible to reduce moisture in the housing by placing therein a drying agent or desiccant. The terms “desiccant” or “drying agents” as used herein, are intended to refer to any material which absorbs water vapor from the air and are thereby able to reduce the moisture in the air inside the housing. However, in order to maintain low moisture content in the functional space of non-hermetically sealed housings for an extended period of time, quite a big portion of the system space should be allocated for storing drying agents. In those cases where the space is small and weight is critical, this solution is also not practical.

Another method to resolve the moisture problem in an enclosure is to fill it with moisture-free gas, e.g., nitrogen, at a pressure higher than the ambient pressure. This “overpressure” method requires hermetic sealing of the housing, and therefore, results in costly housings. During the lifetime of the product, this method also requires periodical pressure inspection. Therefore, the “overpressure” method may not be adequate for mass production of low-cost and maintenance-free systems.

### SUMMARY OF THE INVENTION

It is therefore a broad object of the present invention to provide a pressure equalizing housing device in which the penetration capability of moisture and/or other contaminators into the housing, is reduced.

In accordance with the present invention there is therefore provided a pressure-equalizing housing device, comprising a rigid housing having a coupling end and configured to contain at least one instrument, said coupling end of the housing is adapted to be at least indirectly sealable to a radiation transmittable surface, an opening made in a wall of said housing enabling fluid to pass therethrough, said housing and surface delimiting an interior space communicating with the exterior of the housing via said opening, and a pressure-influenced member forming an expandable and retractable volume body, a portion of which member is located adjacent to, or the interior of which member communicates with, said opening, for equalizing the pressure inside and outside said housing.

### BRIEF DESCRIPTION OF THE DRAWINGS

The invention will now be described in connection with certain preferred embodiments with reference to the following illustrative figures so that it may be more fully understood.

With specific reference now to the figures in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIGS. 1A and 1B are schematic side cross-sectional views of the pressure equalizing housing device with an expandable and retractable member in expandable and retractable states;

FIGS. 2A, 2B and 2C are schematic side cross-sectional views of the pressure equalizing housing device with internally located expandable and retractable member in three sequential states, and

FIGS. 3A, 3B, 3C and 3D are perspective and side cross-sectional views of a pressure equalizing housing device with a rotatable window and an external cleaning mechanism.

### DETAILED DESCRIPTION OF THE PREFERRED EMBODIMENTS

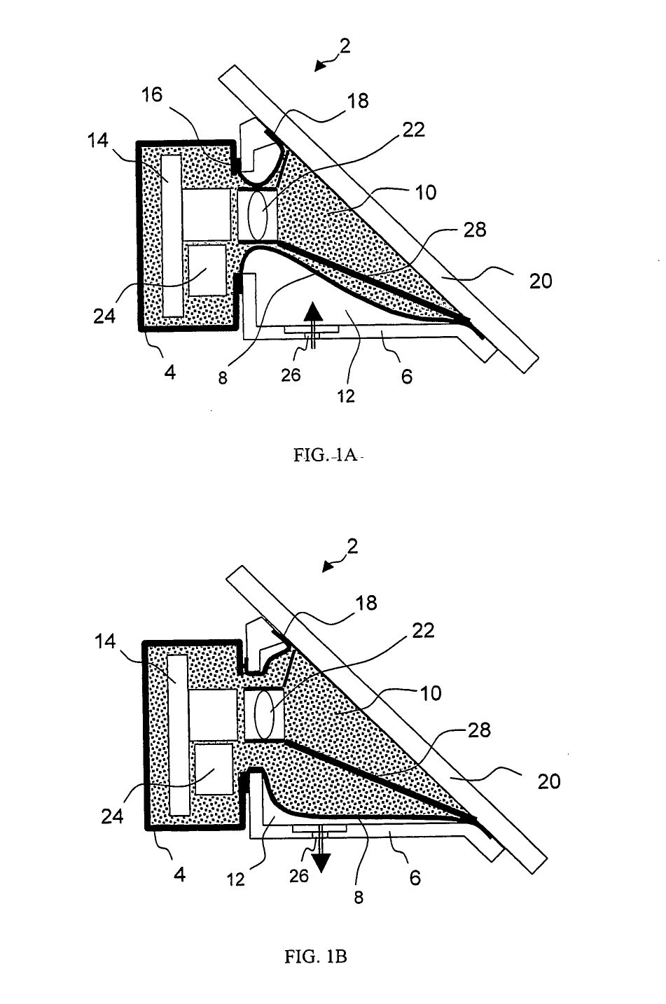

FIGS. 1A and 1B are schematic side cross-sectional views of the pressure equalizing housing device 2 in two operational states. The device 2 consists of a single, rigid housing 4 advantageously, a two-part housing, a first housing part 4 and a second housing part 6, enclosing a fluid, such as air, nitrogen etc., and an expandable and retractable fluid impermeable member 8, e.g., configured as a sleeve, a bellows, a tube or a vessel, acting as a pressure-equalizer based on volume variation under the pressure gradient or a difference of fluid pressure between the interior 10 (hereinafter also referred to as “functional space” 10) of the member 8, and the exterior 12 of the member 8 (hereinafter also referred to as “non-functional space” 12). Continuous volume change of the member 8facilitates maintaining of the pressure difference between the captured fluid in the functional space 10 and the non-functional space 12, e.g., ambient air, as low as possible, thereby reducing the risk of moisture or other contaminators penetration into the functional space 10 of the device. The member 8, illustrated in FIG. 1A in a sleeve-like form is at its reduced volume, which is a result of positive pressure gradient between the ambient air and the functional space 10. The pressure gradient drives the ambient air into the non-functional space 12, by deforming, i.e., retracting the member 8 to assume a reduced volume.

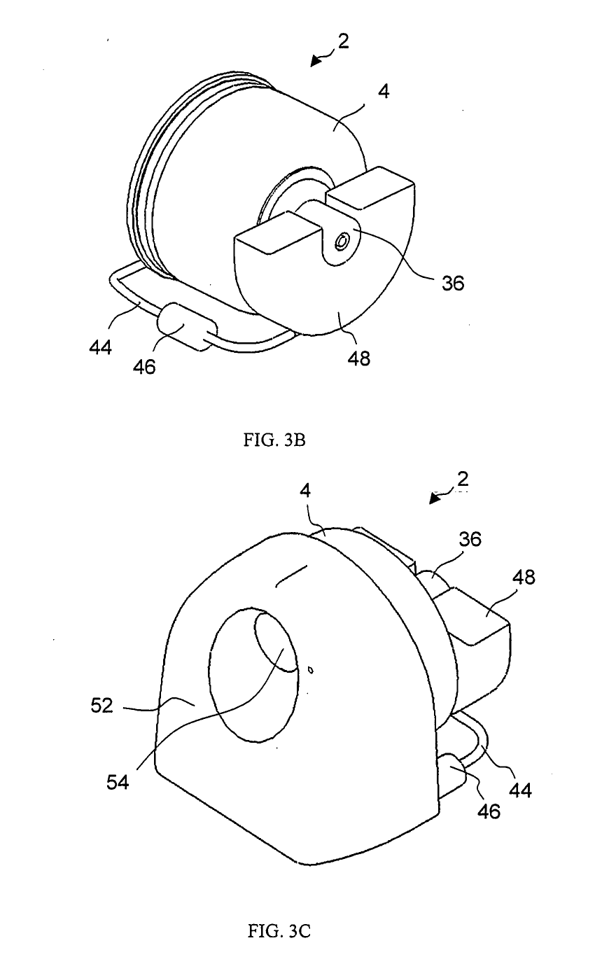

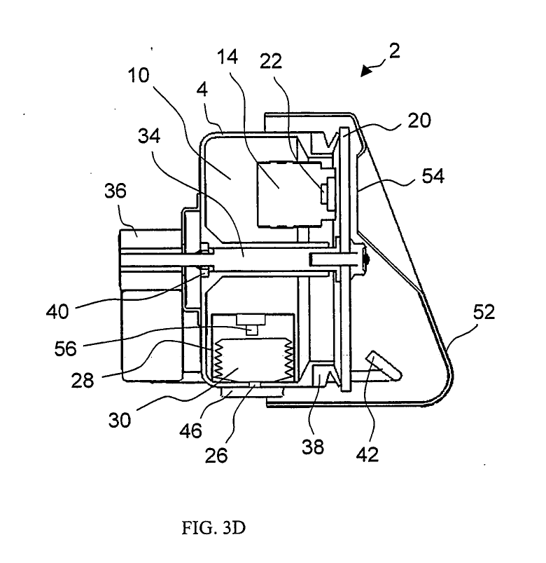

The pressure equalizing housing device 2 illustrated in FIGS. 1A and 1B contains an electro-optical instrument 14, e.g., a camera module, disposed within the housing part 4. The member 8 is in the form of a sleeve having a back end 16 and a front end 18. The housing part 6 may optionally be an integral part of the housing part 4, or can be hermetically coupled to the back end 16 of the member 8. The front end 18 of the member 8 is attachable to a radiation transmittable surface 20, e.g., a car window screen or a housing window capable of transmitting signals of or to the instrument 14, e.g., light rays or electro-magnetic radiation. The member 8, the housing part 4 and the radiation transmittable surface 20, together form a clean functional space 10 for the camera module 14, and for the optical element 22, e.g., a camera lens. The elastic front end 18 of the member 8, or alternatively, a sealer (as shown in FIGS. 3A to 3D) prevents air/moisture penetration through the contact line between the housing device 2 and the surface 20, and optionally, also compensates for concave-shaped transparent surfaces. Water vapors, initially captured within the functional space 10 during the installation, or continuously diffused through the material of the member 8, are absorbed by a small amount of drying agent 24 disposed in the functional space 10. Thus, the risk of water condensation over the optical surface 22 and over the surface 20, as a result of captured moisture and/or of diffusion, is negligible. The ambient air around the device 2 and that which enters the non-functional space 12 through an opening 26, may carry significant amounts of moisture, however the pressure equalizing mechanism of the member 8 neutralizes the drive of this moisture, to prevent penetration into the functional space 10 of the device 2.

FIG. 1B is a schematic side cross-sectional view of the pressure equalizing housing device 2 with the member 8 at its maximal volume. The positive pressure gradient between the functional space 10 and ambient air drives the ambient air out of the non-functional space 12, while deforming the member 8 to its maximum volume. The increase in the volume of the fluid captured within the functional space, results in a pressure decrease, and sequentially reduces the risk of relatively dry captured air of functional space 10 from escaping the housing of the device 2. By keeping the dry and clean air inside the functional space 10 from escaping, a low level of moisture over a long period of time, is maintained.

The member 8 is delimited by the rigid housing part 6 and mechanical delimiter 28, which provide it with a structural support during the volume variation and also with mechanical protection, and delimits the volume of the member 8, to avoid interference with the optical field-of-view of the instrument 14. The space between the exterior of the member 8 and the interior of the rigid housing part 6 is continuously “breathing”, by the volume variation of the member 8, subject to the pressure gradient. This breathing space is controlled by the opening 26 located in the rigid housing part 6 and provides an air pathway between the ambient and the non-functional space 12 of the housing device 2.

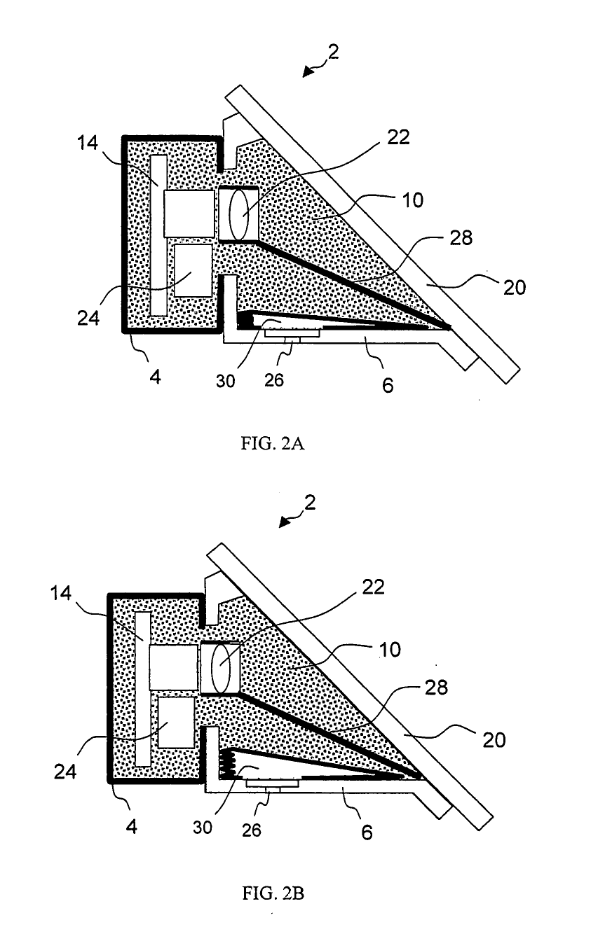

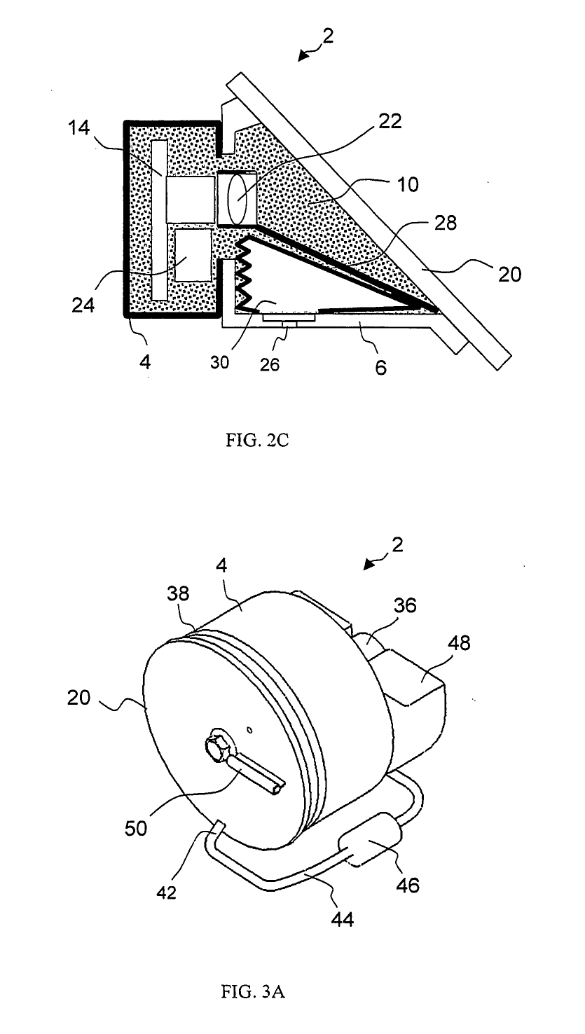

FIGS. 2A, 2B and 2C are three sequential, schematic side cross-sectional views of the pressure equalizing housing device 2 with an internally located expandable and retractable member in the form of a bellows 30. The expandable bellows 30 is preferably made of a fluid impermeable material and hermetically connected to the opening 26. Seen is a sequence of three stages of air intake into the bellows 30 under a positive pressure gradient between the ambient air and the functional space 10, driving the ambient air into the bellows 30 and deforming it to its maximum volume.

It should be understood that the bellows 30 may just as well be located outside the housing, in which case, the functional space 10 is the space extending from within the housing through the opening 26 into the bellows 30.

The operation of this embodiment is similar to that described above. Whenever the functional space 10 is sealed and capable of maintaining a certain level of overpressure, it can initially be inflated, up to a predetermined level of overpressure, by a moisture-free gas, e.g., dry air, thus improving its resistance to moisture and/or other contaminators penetration/diffusion. Optionally, whenever the ambient air is relatively clean and dry, the overpressure can be naturally built up by a release valve (not shown), which enables ambient air inlet into the functional space 10 above a predetermined level of pressure gradient. The pressure gradient should be higher than the pressure gradient needed to inflate/deflate the expandable bellows 30. The implementation of a release valve (one or two-directional) avoids collapsing and/or overstressing of the rigid housing, when structured of light materials, as may be required in mass production products.

To reduce the fatigue and wear of the member 8 and to reduce the amount of desiccant 24, the volume of fluid captured within the functional space 10 of the device during the installation, can be decreased to a minimum by a filler. Smaller captured fluid volume will result in a lower demand for intake/discharge to equalize the pressure, and therefore, will allow longer lifetime of the member 8.

The device 2 may be made in a variety of shapes and sizes as required for placing the instruments 14, such as cameras, optics, electronics, communication instruments, sensors, and the like, inside. The housing parts 4 and 6 may be made of a single enclosure or assembled of more than a single piece, as shown in FIGS. 1A, 1B, 2A, 2B and 2C.

When the air pressure inside the functional space 10 drops, or alternatively, the ambient pressure rises, the expandable or retractable bellows 30, responsive to the pressure gradient or difference, is inflated by the ambient air through the opening 26, until the pressure difference between the functional space 10 and non-functional space 12 is eliminated or significantly reduced. Pressure difference decrease will eliminate or significantly reduce the ambient air penetration into the interior functional space.

When the pressure of the functional space rises, e.g., because the thermal cycle, or alternatively, the ambient pressure drops, the expandable or retractable bellows 30 will discharge excessive air until either pressure difference is eliminated or dramatically reduced, or the expandable or retractable bellows 30 reaches its minimum volume.

Since the pressure difference between the functional space 10 and the ambient air is low, rigid housing part 4 and/or 6 may optionally have apertures covered by movable or rotatable parts or surfaces sealed by sealers, e.g., a rotatable surface 20 and a housing part 6 rotatable about housing part 4.

FIGS. 3A to 3D illustrate a pressure equalizing housing device 2 with a rotatable surface 20, e.g., a rotatable window, mounted on a shaft 34. The surface 20 is rotatable either manually or powered by an electrical motor drive 36 through the shaft 34, and is dynamically sealed by a sealer 38. The shaft is similarly dynamically sealed by a sealer 40. As the pressure difference is low, the sealers are capable of capturing dry and clean air inside the functional space 10 and are capable of preventing the ambient air from penetrating into the functional space 10. Optionally, a sprinkler 42, connected by a pipe 44 to a pump 46, which is fed from the water/detergent tank 48, splashes the water/detergent on the window surface externally, to ease the removal of dirt by the stationary preloaded brush and/or wiper 50, while the surface 20 rotates. Most of the window's surface is covered by a cover 52, keeping the window clean of such heavy contaminators as mud and snow, and also keeps the material of the wiper 50, typically rubber, from being exposed to direct sun radiation or from being blocked by the heavy contaminators. The cover 52 has an aperture 54 that corresponds to the field-of-view of the electro-optical instrument 14. Whenever the device is subject to extreme temperature changes, which may inflate the member 8 to its maximum volume without fully eliminating the pressure gradient, a fluid heating element (not shown), optionally supported by a fluid vent (not shown), both controllable by an electric switch 56, activatable by member 8, can be affixed inside the functional space 10, as for example seen in FIG. 3D. Under high pressure gradient between the ambient and the functional space fluid, this arrangement may reduce penetration of contaminants in the ambient air into the functional space 10 by raising the temperature/pressure. The fluid heating also results in the reduction of the risk of moisture condensation on the interior surface 20 and on the optical element 22.

It will be evident to those skilled in the art that the invention is not limited to the details of the foregoing illustrated embodiments and that the present invention may be embodied in other specific forms without departing from the spirit or essential attributes thereof. The present embodiments are therefore to be considered in all respects as illustrative and not restrictive, the scope of the invention being indicated by the appended claims rather than by the foregoing description, and all changes which come within the meaning and range of equivalency of the claims are therefore intended to be embraced therein.

1-21. (canceled)

22. A pressure-equalizing device, comprising:
a housing having a coupling end and configured to contain at least one instrument;
said coupling end of the housing is adapted to be at least indirectly sealable to an optically transparent surface;
an opening made in a wall of said housing enabling fluid to pass therethrough;
said housing and surface delimiting an interior space communicating with the exterior of the housing via said opening, and
a pressure-influenced member forming an expandable and retractable volume body, a portion of which member is located adjacent to, or the interior of which member communicates with, said opening, for equalizing the pressure inside and outside said housing.

23. The device as claimed in claim 22, wherein said housing is a two-part housing.

24. The device as claimed in claim 23, wherein the at least one instrument is disposed in one part of said two-part housing.

25. The device as claimed in claim 23, wherein said member is disposed in one part of said two-part housing.

26. The device as claimed in claim 23; wherein said opening is made in a wall of one part of said two-part housing.

27. The device as claimed in claim 22, wherein said member is a sleeve-like member having a first edge and a second edge.

28. The device as claimed in claim 27, wherein said first edge is attached to said coupling end and said second edge is, at least indirectly, attached to said optically transparent surface.

29. The device as claimed in claim 22, wherein said member is a bellows having an interior which communicates with said opening.

30. The device as claimed in claim 29, wherein said bellows is disposed outside said housing.

31. The device as claimed in claim 23, wherein at least one part of the housing contains a desiccant for removing moisture.

32. The device as claimed in claim 22, wherein said instrument is selected from the group of instruments including sensors, optical, electro-optical, electro-magnetic, radiation transmitting or communication instruments.

33. The device as claimed in claim 22, wherein said member is made of a fluid impermeable material.

34. The device as claimed in claim 22, wherein said housing has two mutually rotatable parts.

35. The device as claimed in claim 22, wherein said housing includes at least one aperture covered by a movable or rotatable surface sealingly coupled thereto.

36. The device as claimed in claim 35, wherein said movable or rotatable surface is adapted to be driven manually.

37. The device as claimed in claim 22, wherein said optically transparent surface is a rotatable window sealingly coupled to said housing.

38. The device as claimed in claim 37, further comprising a cleaning element adapted to contact an external surface of said window during rotation of the window, for cleaning said external surface.

39. The device as claimed in claim 22, further comprising an electric switch controllable by said member.

40. The device as claimed in claim 39, wherein said electric switch activates a fluid heating element, and/or a fluid vent

41. The device as claimed in claim 35, wherein said movable or rotatable surface is adapted to be powered by a motor.
